(19) United States
(12) Patent Application Publication
(10) Pub. No.: US 2026/0190779 A1
(43) Pub. Date: Jul. 2, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventor: Kyoungsub So, YONGIN-SI (KR)

(21) Appl. No.: 19/374,150

(22) Filed: Oct. 30, 2025

(30) Foreign Application Priority Data
Dec. 27, 2024 (KR) 10-2024-0199336

(51) Int. Cl. H10K 59/80

(52) U.S. Cl. CPC H10K 59/873

(57) ABSTRACT

A display device includes a display panel including a display area and a peripheral area proximate to the display area. The peripheral area includes a bending area extending from the display area. An adhesive layer is disposed on the display panel. A side surface of the adhesive layer includes an inclined surface. A glass window is disposed on the adhesive layer and protrudes toward the peripheral area to a greater extent than the adhesive layer area. An optical functional layer is disposed on the glass window. An end of the optical functional layer is between a boundary where the adhesive layer and the display panel meet and a boundary between the display area and the peripheral area. A filler is disposed in the peripheral area, covering top, bottom, and side surfaces of the glass window and the side surface of the adhesive layer.

### CROSS-REFERENCE TO RELATED APPLICATION

This application claims priority under 35 U.S.C. § 119 to Korean Patent Application No. 10-2024-0199336, filed on Dec. 27, 2024, in the Korean Intellectual Property Office, the disclosure of which is incorporated by reference herein in its entirety.

### TECHNICAL FIELD

The present disclosure relates to a display device and an electronic device including the same.

### DISCUSSION OF THE RELATED ART

Display devices are used to visually present data and can be found in both in small products, such as a mobile phone, and in larger products, such as televisions.

These devices contain many pixels that receive electrical signals and emit light to produce images. In organic light-emitting diode (OLED) display devices, each pixel includes an OLED that generates light on its own. Generally, an OLED display consists of a thin-film transistor and an OLED layer mounted on a substrate.

As display devices have become more widely used in various applications, efforts to improve display quality through new designs have increased.

### SUMMARY

A display device includes a display panel including a display area and a peripheral area proximate to the display area. The peripheral area includes a bending area extending from the display area. An adhesive layer is disposed on the display panel. A side surface of the adhesive layer is inclined. A glass window is disposed on the adhesive layer and protrudes towards the peripheral area to a greater extent than the adhesive layer. An optical functional layer is disposed on the glass window. An end of the optical functional layer is between a boundary where the adhesive layer and the display panel meet and a boundary between the display area and the peripheral area. A filler is disposed in the peripheral area, covering top, bottom, and side surfaces of the glass window and the side surface of the adhesive layer.

The filler may be disposed over the entire side surface of the adhesive layer, covering a top of the side surface of the adhesive layer.

The display panel may be bent in the bending area such that bottom surfaces thereof may face each other.

The filler may cover a top surface of the display panel in the bending area.

The filler may fill a space between the bottom surfaces of the display panel facing each other in the bending area.

The filler may cover a side surface of the optical functional layer.

The display panel may include a substrate, a display layer, and an encapsulation layer.

The display device may further include a cover window disposed on the display panel.

A display device includes a display panel including a display area and a peripheral area proximate to the display area. The peripheral area includes a bending area extending from the display area. An adhesive layer is disposed on the display panel. A side surface of the adhesive layer is straight. A glass window is disposed on the adhesive layer and protrudes toward the peripheral area to a greater extent than the adhesive layer. An optical functional layer is disposed on the glass window. An end of the optical functional layer is between the side surface of the adhesive layer and a boundary between the display area and the peripheral area. A filler is disposed in the peripheral area, covering top, bottom, and side surfaces of the glass window and the side surface of the adhesive layer.

The filler may cover a top of the side surface of the adhesive layer.

The display panel may be bent in the bending area such that bottom surfaces thereof may face each other.

The filler may cover a top surface of the display panel in the bending area.

The filler may fill a space between the bottom surfaces of the display panel facing each other.

The filler may cover a side surface of the optical functional layer.

A display device includes a display panel including a display area and a peripheral area proximate to the display area. The peripheral area includes a bending area extending from the display area. An adhesive layer is disposed on the display panel. A side surface of the adhesive layer is straight. A protection film is disposed on the adhesive layer. An optical functional layer is disposed on the glass window. An end of the optical functional layer is between the side surface of the adhesive layer and a boundary between the display area and the peripheral area. A filler is disposed in the peripheral area, covering top and side surfaces of the protection film and the side surface of the adhesive layer.

The side surface of the protection film and the side surface of the adhesive layer may be in line with one another.

The filler may cover a top of the side surface of the adhesive layer.

The display panel may be bent in the bending area such that bottom surfaces thereof may face each other.

The filler may cover a top surface of the display panel in the bending area and fill a space between the bottom surfaces of the display panel.

The filler may cover a side surface of the optical functional layer.

An electronic device includes a display panel including a display area and a peripheral area proximate to the display area. The peripheral area includes a bending area extending from the display area. An adhesive layer is disposed on the display panel. A side surface of the adhesive layer is inclined. A glass window is disposed on the adhesive layer and protrudes toward the peripheral area to a greater extent than the adhesive layer. An optical functional layer is disposed on the glass window. An end of the optical functional layer is between a boundary where the adhesive layer and the display panel meet and a boundary between the display area and the peripheral area. A filler is disposed in the peripheral area, covering top, bottom, and side surfaces of the glass window and the side surface of the adhesive layer. A bottom cover constitutes an exterior of the electronic device. A front surface of the bottom cover includes an opening exposing a portion of the display panel.

An electronic device includes a display panel including a display area and a peripheral area proximate to the display area. The peripheral area includes a bending area extending from the display area. An adhesive layer is disposed on the display panel. A side surface of the adhesive layer is straight. A glass window is disposed on the adhesive layer and protrudes toward the peripheral area to a greater extent than the adhesive layer. An optical functional layer is disposed on the glass window. An end of the optical functional layer is between the side surface of the adhesive layer and a boundary between the display area and the peripheral area. A filler is disposed in the peripheral area, covering top, bottom, and side surfaces of the glass window and the side surface of the adhesive layer. A bottom cover constitutes an exterior of the electronic device. A front surface of the bottom cover includes an opening exposing a portion of the display panel.

An electronic device includes a display panel including a display area and a peripheral area proximate to the display area. The peripheral area includes a bending area extending from the display area. An adhesive layer is disposed on the display panel. A side surface of the adhesive layer is straight. A protection film is disposed on the adhesive layer. An optical functional layer is disposed on the glass window. An end of the optical functional layer is between the side surface of the adhesive layer and a boundary between the display area and the peripheral area. A filler is disposed in the peripheral area, covering top and side surfaces of the protection film and the side surface of the adhesive layer. A bottom cover constitutes an exterior of the electronic device. A front surface of the bottom cover includes an opening exposing a portion of the display panel.

### BRIEF DESCRIPTION OF THE DRAWINGS

The above and other aspects and features of certain embodiments of the disclosure will be more apparent from the following description taken in conjunction with the accompanying drawings, in which:

FIG. 1A is a perspective view of an electronic device according to an embodiment;

FIG. 1B is an exploded view of an electronic device according to an embodiment;

FIG. 2 is a block diagram of a central processing unit according to an embodiment;

FIG. 3 is a schematic diagram illustrating an electronic device according to various embodiments;

FIG. 4 is a schematic equivalent circuit diagram of a sub-pixel circuit included in a display device, according to an embodiment;

FIG. 5 is a cross-sectional view of a display panel according to an embodiment; and

FIGS. 6 to 8 are cross-sectional views of a display device according to embodiments.

### DETAILED DESCRIPTION

Reference will now be made in detail to embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments are described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not necessarily be construed as being limited to the descriptions set forth herein.

One or more embodiments will be described below in more detail with reference to the accompanying drawings. Those elements that are the same or are in correspondence with each other are rendered the same reference numeral regardless of the figure number, and to the extent that an element is not described in detail with respect to this figure, it may be understood that the element is at least similar to a corresponding element that has been described elsewhere within the present disclosure.

While such terms as “first” and “second” may be used to describe various elements, such elements are not necessarily be limited to the above terms. The above terms are used to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. For example, for example, intervening layers, regions, or elements may be present.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When an embodiment may be implemented differently, a certain process order may be performed differently from the described order. For example, two consecutively described processes may be performed substantially at the same time or performed in an order opposite to the described order.

As used herein, the expression “A and/or B” refers to A, B, or A and B. In addition, the expression “at least one of A and B” refers to A, B, or A and B.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The x-axis, the y-axis, and the z-axis are not necessarily limited to three axes of the Cartesian coordinate system and may be interpreted in a broader sense. For example, the x-axis, the y-axis, and the z-axis may be perpendicular to one another or may represent different directions that are not perpendicular to one another.

Exemplary embodiments of the present disclosure relate to display device, such as one that is flexible or curved, having a specialized edge sealing and light-blocking structure used to improve reliability, image quality, and durability. According to this approach, a glass layer is positioned on an adhesive layer over the display panel. An optical functional layer (like an anti-reflective or polarizing layer) is arranged on the glass. A filler material is applied strategically in the peripheral area, covering the top, bottom, and sides of the glass and adhesive layers. This filler also covers or fills in the bending area, and blocks light leakage through side surfaces of the adhesive or glass, which is a critical challenge in flexible displays.

The result is a sealed and optically optimized edge region that prevents light leakage (which can degrade image quality and aesthetics) and reinforces the mechanical stability of bendable portions of the display.

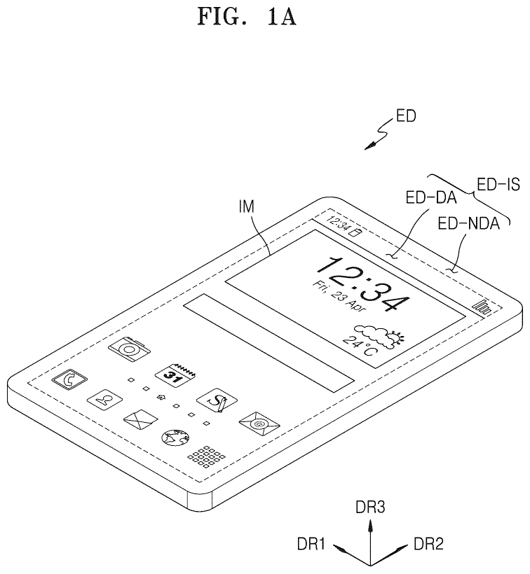

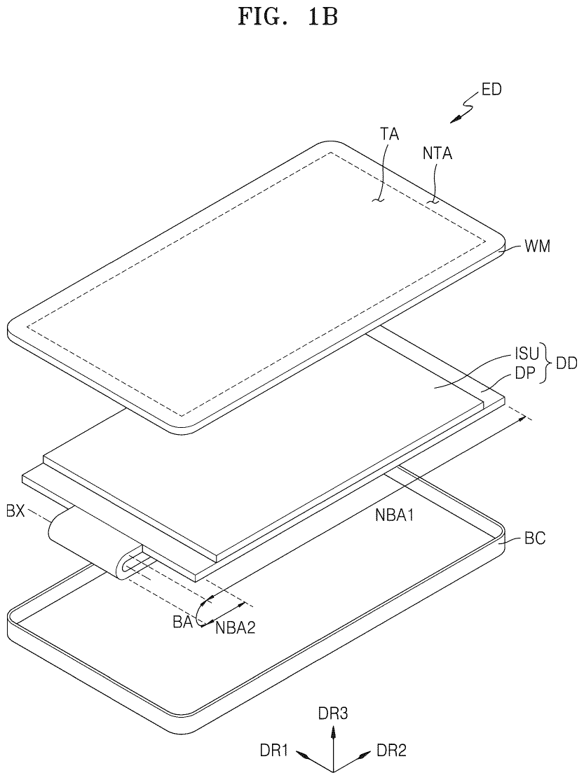

FIG. 1A is a perspective view of an electronic device ED according to an embodiment. FIG. 1B is an exploded view of the electronic device ED according to an embodiment.

In the present description, an electronic device of a mobile phone terminal is shown as an example. The electronic device ED described herein may be applied to large-sized electronic devices, such as a television (TV) and a computer monitor, and may also be applied to small and medium-sized electronic devices, such as a tablet computer, a vehicle navigation system, a portable game console, and a smartwatch.

Referring to FIG. 1A, the electronic device ED may display an image IM on a display surface ED-IS. Icon images are shown as an example of the image IM. The display surface ED-IS is parallel to a plane defined by a first direction DR1 and a second direction DR2. A third direction DR3 indicates a normal direction of the display surface ED-IS, for example, a thickness direction of the electronic device ED.

As used herein, the phrase “when viewed in plan” or “in a plan view” may refer to when viewed in the third direction DR3. The third direction DR3 differentiates a front (or top) surface and a rear (or bottom) surface of each layer or unit described below. However, a combination of the first to third directions DR1 to DR3 may be changed to another combination.

Referring to FIG. 1B, the electronic device ED may include a window WM, a display device DD, and an accommodation member BC. The electronic device ED may further include an optical element disposed between the window WM and the display device DD. The optical element may include a polarizer.

The window WM may be disposed on the display device DD and may transmit an image provided from the display device DD to the outside. The window WM includes a transmission area TA and a non-transmission area NTA. The transmission area TA may overlap a display area ED-DA and may have a shape corresponding to a shape of the display area ED-DA. The window WM may include a base layer and functional layers disposed on the base layer. The functional layers may include a protective layer and an anti-fingerprint layer. The base layer of the window WM may be formed of glass, sapphire, or plastic.

The non-transmission area NTA may overlap a non-display area ED-NDA and may have a shape corresponding to a shape of the non-display area ED-NDA. The non-transmission area NTA may be an area having a relatively low light transmittance compared to that of the transmission area TA. The non-transmission area NTA may be defined by a bezel pattern disposed in a partial region of the base layer of the window WM, and an area in which the bezel pattern is not disposed may be defined as the transmission area TA. However, one or more embodiments are not necessarily limited thereto, and the non-transmission area NTA may be omitted.

According to an embodiment, a display panel DP may be one of a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel, and is not particularly limited. Hereinafter, it is assumed that the display panel DP is an organic light-emitting display panel.

An input sensor ISU may include one of a capacitive sensor, an optical sensor, an ultrasonic sensor, and an inductive sensor. The input sensor ISU may be formed on the display panel DP through a continuous process, or may be manufactured separately and then attached to an upper side of the display panel DP through an adhesive layer, and is not necessarily limited to any one embodiment.

The display device DD may further include a driving chip and a circuit board. Although an embodiment in which the driving chip is mounted on the display panel DP is shown, one or more embodiments are not necessarily limited thereto. The driving chip may generate a driving signal required for an operation of the display panel DP based on a control signal transferred from the circuit board.

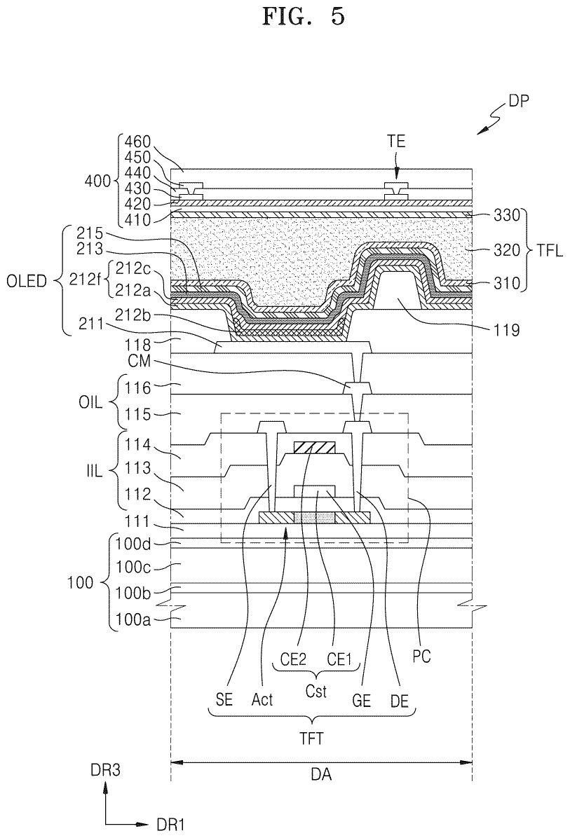

The circuit board electrically bonded to the display panel DP may be bent and disposed on a rear surface of the display panel DP. The accommodation member BC may receive the display device DD and may be coupled to the window WM. The circuit board may be disposed at an end of a base substrate 100 (refer to FIG. 5) and may be electrically connected to a circuit element layer. The electronic device ED may further include a mainboard, and electronic modules, a camera module, and a power module mounted on the mainboard.

The display panel DP, according to an embodiment, may include a bending area BA, and a first non-bending area NBA1 and a second non-bending area NBA2 spaced apart from each other in the first direction DR1 with the bending area BA interposed therebetween.

The bending area BA may be defined as an area where the display panel DP is bent along a virtual bending axis BX extending in the second direction DR2. The first non-bending area NBA1 may be defined as an area overlapping the transmission area TA, and the second non-bending area NBA2 may be defined as an area to which the circuit board is connected.

When the bending area BA is bent with respect to the bending axis BX, the circuit board and the driving chip may be bent in a direction of the rear surface of the display panel DP and disposed on the rear surface of the display panel DP.

Additional elements may be disposed to compensate for a step between the circuit board and the rear surface of the display panel DP caused by the bending area BA.

According to an embodiment, in the second direction DR2, a width of the first non-bending area NBA1 may be greater than widths of the bending area BA and the second non-bending area NBA2. However, one or more embodiments are not necessarily limited thereto, and a width of the bending area BA in the second direction DR2 may decrease in a direction from the first non-bending area NBA1 to the second non-bending area NBA2 and is not necessarily limited to any one embodiment.

A mobile phone terminal has been described above as an example of the electronic device ED. However, in the present description, it is sufficient for the electronic device ED to include two or more electrically bonded electronic components. The display panel DP and the driving chip mounted on the display panel DP may correspond to different electronic components, respectively, and these two may be sufficient to constitute the electronic device ED, and one or more embodiments are not necessarily limited thereto.

For example, the display panel DP and the circuit board connected to the display panel DP may be sufficient to constitute the electronic device ED, and a mainboard and an electronic module mounted on the mainboard may be sufficient to constitute the electronic device ED. Hereinafter, the electronic device ED, according to one or more embodiments, will be described focusing on a bonding structure between the display panel DP and the driving chip mounted on the display panel DP.

A display device, according to one or more embodiments, may be applicable to various electronic devices. An electronic device according to an embodiment may include the above display device and may further include a module or device having another additional function in addition to the display device.

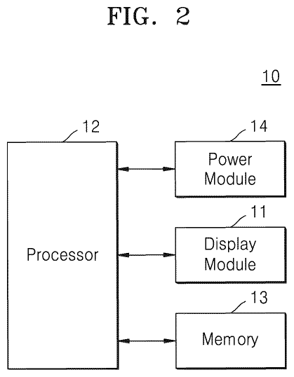

FIG. 2 is a block diagram of an electronic device 10 according to an embodiment. Referring to FIG. 2, the electronic device 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

Data information required for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module configured to convert power supplied by the power supply module to generate power required for an operation of the electronic device 10.

At least one of the above elements of an electronic device may be included in a display device according to the above embodiments. In some embodiments, some of the individual modules functionally included in one module may be included in the display device, and the others may be provided separately from the display device. For example, the display device may include the display module 11, and the processor 12, the memory 13, and the power module 14 may be provided in the form of a device other than the display device in the electronic device.

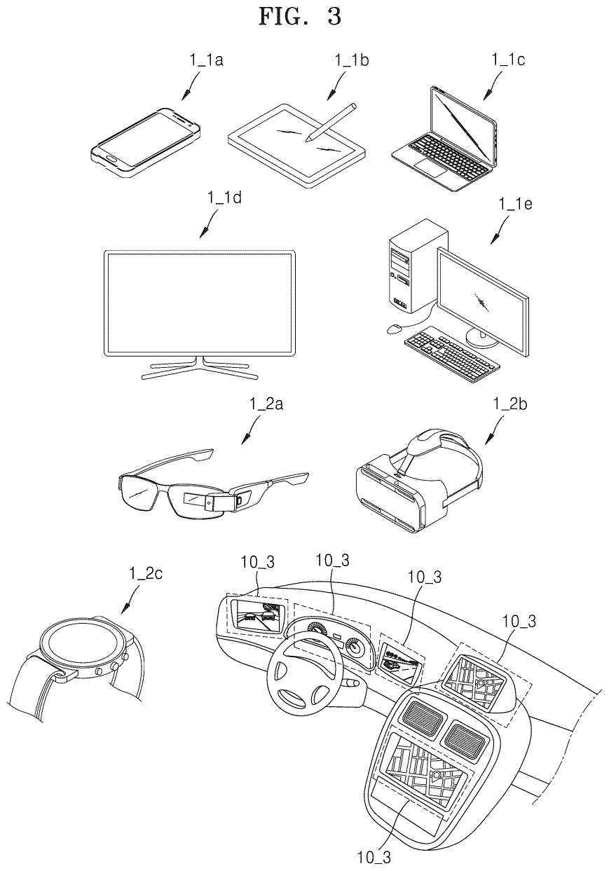

FIG. 3 schematically shows an electronic device according to various embodiments.

Referring to FIG. 3, various electronic devices to which a display device according to embodiments is applied may include not only electronic devices for image display, such as a smartphone 10_1a, a tablet computer 10_1b, a laptop/notebook computer 10_1c, a TV 10_1d, and a computer monitor 10_1e, but also wearable electronic devices including display modules such as smart glasses 10_2a, a head-mounted display 10_2b, and a smartwatch 10_2c, and automotive electronic devices 10_3 including display modules such as a car's instrument cluster, a center information display (CID) disposed on a car's center fascia or dashboard, and a room mirror display.

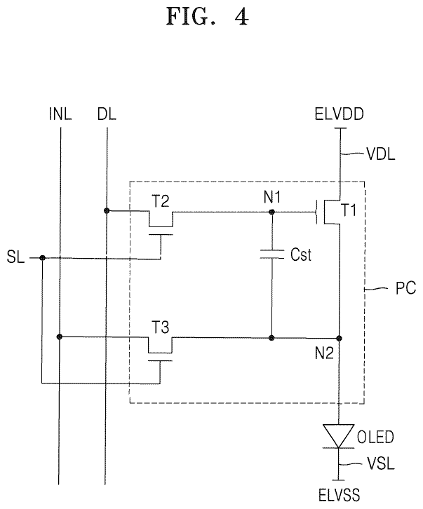

FIG. 4 is a schematic equivalent circuit diagram of a sub-pixel circuit PC included in a display device, according to an embodiment.

Referring to FIG. 4, the sub-pixel circuit PC may include a plurality of thin-film transistors and at least one capacitor. In an embodiment, the sub-pixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor thin-film transistor including a semiconductor layer composed of an oxide semiconductor, or a silicon semiconductor thin-film transistor including a semiconductor layer composed of polysilicon. Each thin-film transistor may include a first electrode and a second electrode, and depending on the type of a thin-film transistor, the first electrode may be one of a source electrode and a drain electrode and the second electrode may be the other of the source electrode and the drain electrode. In addition, each thin-film transistor may include a gate electrode.

The first thin-film transistor T1 may be a driving thin-film transistor. A first electrode of the first thin-film transistor T1 may be connected to a driving voltage line VDL configured to supply a driving power voltage ELVDD, and a second electrode of the first thin-film transistor T1 may be connected to a pixel electrode of an organic light-emitting diode OLED. A gate electrode of the first thin-film transistor T1 may be connected to a first node N1. The first thin-film transistor T1 may be configured to control an amount of current flowing through the organic light-emitting diode OLED from the driving power voltage ELVDD in response to a voltage of the first node N1.

The second thin-film transistor T2 may be a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. When a scan signal is supplied to the scan line SL, the second thin-film transistor T2 may be turned on to electrically connect the data line DL and the first node N1 to each other.

The third thin-film transistor T3 may be an initialization thin-film transistor and/or a sensing thin-film transistor. A first electrode of the third thin-film transistor T3 may be connected to a second node N2, and a second electrode of the third thin-film transistor T3 may be connected to an initialization voltage line INL. A gate electrode of the third thin-film transistor T3 may be connected to the scan line SL.

When a scan signal is supplied to the scan line SL, the third thin-film transistor T3 may be turned on to electrically connect the initialization voltage line INL and the second node N2 to each other. In some embodiments, the third thin-film transistor T3 may be turned on according to a signal received through the scan line SL to transfer an initialization voltage from the initialization voltage line INL to the pixel electrode of the organic light-emitting diode OLED and initialize the pixel electrode of the organic light-emitting diode OLED.

In some embodiments, when a scan signal is supplied to the scan line SL, the third thin-film transistor T3 may be turned on to sense characteristic information regarding the organic light-emitting diode OLED. The third thin-film transistor T3 may have both of the above-described functions as an initialization thin-film transistor and a sensing thin-film transistor or may have either function. An initialization operation and a sensing operation of the third thin-film transistor T3 may each be performed individually or may be performed simultaneously. When the third thin-film transistor T3 has the function as a sensing thin-film transistor, the initialization voltage line INL may be referred to as a sensing line.

The storage capacitor Cst may be connected between the first node N1 and the second node N2. For example, a first capacitor plate of the storage capacitor Cst may be connected to the gate electrode of the first thin-film transistor T1, and a second storage plate of the storage capacitor Cst may be connected to the pixel electrode of the organic light-emitting diode OLED.

An opposite electrode of the organic light-emitting diode OLED may be connected to a common voltage line VSL configured to provide a common power voltage ELVSS.

Although FIG. 4 shows the sub-pixel circuit PC including three thin-film transistors and one storage capacitor, one or more embodiments are not necessarily limited thereto. In an embodiment, the number of thin-film transistors or the number of storage capacitors may be variously modified according to the design of the sub-pixel circuit PC.

FIG. 5 is a schematic cross-sectional view of the display panel DP according to an embodiment.

Referring to FIG. 5, the base substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction of the base substrate 100.

At least one of the first base layer 100a and the second base layer 100c may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer 100b and the second barrier layer 100d are barrier layers that prevent intrusion of external foreign substances and may each have a single-layer or multi-layer structure including an inorganic material such as silicon nitride (SiNX), silicon oxide (SiO₂) and/or silicon oxynitride (SiON).

A buffer layer 111 may be disposed on the base substrate 100. The buffer layer 111 may include an inorganic insulating material such as silicon nitride (SiNX), silicon oxynitride (SiON) and silicon oxide (SiO₂), and may have a single-layer or multi-layer structure including the above-described inorganic insulating material.

An inorganic insulating layer IIL may be disposed on the buffer layer 111. The inorganic insulating layer IIL may include a first gate insulating layer 112, a second gate insulating layer 113, and an interlayer insulating layer 114.

The sub-pixel circuit PC may be disposed in the display area DA. The sub-pixel circuit PC may include a thin-film transistor TFT and the storage capacitor Cst. The thin-film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. Alternatively, the semiconductor layer Act may include amorphous silicon, an oxide semiconductor, or an organic semiconductor. The semiconductor layer Act may include a channel region, and a drain region and a source region respectively disposed on both sides of the channel region.

The gate electrode GE may be disposed over the semiconductor layer Act. The gate electrode GE may overlap the channel region. The gate electrode GE may include a low-resistance metal material (e.g., a metal having a relatively low electrical resistance). The gate electrode GE may include a conductive material including molybdenum (Mo), aluminum (Al), copper (Cu), titanium (Ti), etc., and may have a multi-layer or single-layer structure including the above-described material.

The first gate insulating layer 112 may be disposed between the semiconductor layer Act and the gate electrode GE. The first gate insulating layer 112 may include an inorganic insulating material, such as silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second gate insulating layer 113 may be disposed on the gate electrode GE. The second gate insulating layer 113 may cover the gate electrode GE. The second gate insulating layer 113 may include an inorganic insulating material, such as silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second capacitor plate CE2 of the storage capacitor Cst may be disposed on the second gate insulating layer 113. The second capacitor plate CE2 may overlap the gate electrode GE disposed below the second capacitor plate CE2. In this regard, the gate electrode GE and the second capacitor plate CE2 overlapping each other with the second gate insulating layer 113 therebetween may constitute the storage capacitor Cst. For example, the gate electrode GE may serve as a first capacitor plate CE1 of the storage capacitor Cst.

As described above, the storage capacitor Cst and the thin-film transistor TFT may overlap each other. However, one or more embodiments are not necessarily limited thereto. For example, the storage capacitor Cst might nit overlap the thin-film transistor TFT. For example, the first capacitor plate CE1 of the storage capacitor Cst may be spaced apart from the gate electrode GE of the thin-film transistor TFT as a separate element from the gate electrode GE of the thin-film transistor TFT.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including the above-described material.

The interlayer insulating layer 114 may be disposed on the second capacitor plate CE2. The interlayer insulating layer 114 may cover the second capacitor plate CE2. The interlayer insulating layer 114 may include silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnO). The interlayer insulating layer 114 may have a single-layer or multi-layer structure including the above-described inorganic insulating material.

Each of the drain electrode DE and the source electrode SE may be on the interlayer insulating layer 114. Each of the drain electrode DE and the source electrode SE may be connected to the semiconductor layer Act through a contact hole defined in the first gate insulating layer 112, the second gate insulating layer 113, and the interlayer insulating layer 114. The drain electrode DE and the source electrode SE may include a highly conductive material. The drain electrode DE and the source electrode SE may include a conductive material including molybdenum (Mo), aluminum (Al), copper (Cu), titanium (Ti), etc., and may have a multi-layer or single-layer structure including the above-described material. For example, the drain electrode DE and the source electrode SE may have a multi-layer structure of titanium (Ti)/aluminum (Al)/titanium (Ti).

The organic insulating layer OIL may be disposed on the inorganic insulating layer IIL. The organic insulating layer OIL may include a first organic insulating layer 115 and a second organic insulating layer 116. Although FIG. 5 shows the organic insulating layer OIL including two layers, one or more embodiments are not necessarily limited thereto. The organic insulating layer OIL may include three or four layers (or more).

The first organic insulating layer 115 may cover the drain electrode DE and the source electrode SE. The first organic insulating layer 115 may include an organic insulating material such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

A connection electrode CM may be disposed on the first organic insulating layer 115. In this regard, the connection electrode CM may be connected to the drain electrode DE or the source electrode SE through a contact hole in the first organic insulating layer 115. The connection electrode CM may include a highly conductive material (e.g., a material that is as, or more, electrically conductive as the materials listed herein). The connection electrode CM may include a conductive material including molybdenum (Mo), aluminum (Al), copper (Cu), titanium (Ti), etc., and may have a multi-layer or single-layer structure including the above-described material. For example, the connection electrode CM may have a multi-layer structure of titanium (Ti)/aluminum (Al)/titanium (Ti).

The second organic insulating layer 116 may be disposed on the connection electrode CM. The second organic insulating layer 116 may cover the connection electrode CM. The second organic insulating layer 116 may include a material that is the same as or different from that of the first organic insulating layer 115.

A light-emitting diode may be disposed on the second organic insulating layer 116. For example, the organic light-emitting diode OLED may be disposed on the second organic insulating layer 116. Alternatively, an inorganic light-emitting diode, etc., may be disposed on the second organic insulating layer 116.

The organic light-emitting diode OLED may emit red, green, or blue light, or may emit red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be an opposite electrode (e.g., a cathode) of the organic light-emitting diode OLED.

The first electrode 211 may be disposed on the second organic insulating layer 116. The first electrode 211 may be electrically connected to the connection electrode CM through a contact hole defined in the second organic insulating layer 116. The first electrode 211 may include conductive oxide, such as indium tin oxide (ITO), indium zinc oxide (IZO), zinc oxide (ZnO), indium oxide (In2O3), indium gallium oxide (IGO), or aluminum zinc oxide (AZO). In an embodiment, the first electrode 211 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the first electrode 211 may further include a layer on/under the above-described reflection layer and formed of ITO, IZO, ZnO, or In2O3. For example, the first electrode 211 may have a multi-layer structure of ITO/Ag/ITO.

A pixel-defining layer 118 in which an opening exposing at least a portion of the first electrode 211 is defined may be disposed on the first electrode 211. An emission area of light emitted from the organic light-emitting diode OLED may be defined by the opening defined in the pixel-defining layer 118. For example, a width of the opening may correspond to a width of the emission area.

The pixel-defining layer 118 may include an organic insulating material. Alternatively, the pixel-defining layer 118 may include an inorganic insulating material, such as silicon nitride, silicon oxynitride, or silicon oxide. Alternatively, the pixel-defining layer 118 may include an organic insulating material and an inorganic insulating material. In an embodiment, the pixel-defining layer 118 may include a light-blocking material. The light-blocking material may include carbon black, carbon nanotubes, resin or paste including black dye, metal particles, for example, nickel, aluminum, molybdenum, and alloys thereof, metal oxide particles (e.g., chromium oxide), or metal nitride particles (e.g., chromium nitride). When the pixel-defining layer 118 includes a light-blocking material, the reflection of external light caused by metal structures disposed below the pixel-defining layer 118 may be reduced.

A spacer 119 may be disposed on the pixel-defining layer 118. The spacer 119 may include an organic insulating material, such as polyimide. Alternatively, the spacer 119 may include an inorganic insulating material such as silicon nitride (SiNX) or silicon oxide (SiO₂), or may include an organic insulating material and an inorganic insulating material.

In an embodiment, the spacer 119 may include the same material as that of the pixel-defining layer 118. In this case, the pixel-defining layer 118 and the spacer 119 may be formed together during a mask process using a halftone mask or the like. Alternatively, the spacer 119 and the pixel-defining layer 118 may include different materials, respectively.

The emission layer 212b may be disposed in the opening of the pixel-defining layer 118. The emission layer 212b may include a high-molecular weight or low-molecular weight organic material emitting light of a certain color.

The functional layer 212f may include a first functional layer 212a and a second functional layer 212c. The first functional layer 212a may be disposed between the first electrode 211 and the emission layer 212b, and the second functional layer 212c may be disposed between the emission layer 212b and the second electrode 213. However, at least one of the first functional layer 212a or the second functional layer 212c may be omitted. Hereinafter, a case where each of the first functional layer 212a and the second functional layer 212c is disposed will be mainly described.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be common layers that entirely cover the base substrate 100 as the second electrode 213 described below does.

The second electrode 213 may be disposed on the functional layer 212f. The second electrode 213 may include a conductive material having a relatively low work function (e.g., a conductive material having a work function that is as low as, or lower than, the materials listed below). For example, the second electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 213 may further include a layer, such as ITO, IZO, ZnO, or In₂O₃, on a (semi)transparent layer including the above-described material.

In an embodiment, the capping layer 215 may be disposed on the second electrode 213. The capping layer 215 may include lithium fluoride (LiF), an inorganic material and/or an organic material.

An encapsulation layer TFL may be disposed on the organic light-emitting diode OLED. The encapsulation layer TFL may cover the organic light-emitting diode OLED. The encapsulation layer TFL may be disposed on the second electrode 213 and/or the capping layer 215. In an embodiment, the encapsulation layer TFL may include at least one inorganic encapsulation layer and at least one organic encapsulation layer. FIG. 5 shows the encapsulation layer TFL including a first inorganic encapsulation layer 310, an organic encapsulation layer 320, and a second inorganic encapsulation layer 330 sequentially stacked on one another.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may have a single-layer or multi-layer structure including the above-described material. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate.

An input sensing layer 400 may be disposed on the encapsulation layer TFL. The input sensing layer 400 may include a first touch insulating layer 410, a second touch insulating layer 420, a first conductive layer 430, a third touch insulating layer 440, a second conductive layer 450, and a planarization layer 460.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may include an inorganic insulating material and/or an organic insulating material. For example, the first touch insulating layer 410 and the second touch insulating layer 420 may include an inorganic insulating material such as silicon oxide, silicon nitride and/or silicon oxynitride.

In an embodiment, at least one of the first touch insulating layer 410 and the second touch insulating layer 420 may be omitted. For example, the first touch insulating layer 410 may be omitted. In this case, the second touch insulating layer 420 may be disposed on the second inorganic encapsulation layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In an embodiment, the third touch insulating layer 440 may include an inorganic insulating material and/or an organic insulating material. For example, the third touch insulating layer 440 may include an inorganic insulating material such as silicon oxide, silicon nitride and/or silicon oxynitride.

The second conductive layer 450 may be disposed on the third touch insulating layer 440. A touch electrode TE of the input sensing layer 400 may have a structure in which the first conductive layer 430 and the second conductive layer 450 are connected to each other. Alternatively, the touch electrode TE may be formed in one of the first conductive layer 430 and the second conductive layer 450 and may include a metal line included in the corresponding conductive layer. Each of the first conductive layer 430 and the second conductive layer 450 may include at least one of aluminum (Al), copper (Cu), titanium (Ti), molybdenum (Mo), and indium tin oxide (ITO), and may have a single-layer or multi-layer structure including the above-described material. For example, each of the first conductive layer 430 and the second conductive layer 450 may have a three-layer structure of a titanium layer/an aluminum layer/a titanium layer.

In an embodiment, the planarization layer 460 may cover the second conductive layer 450. The planarization layer 460 may include an organic insulating material.

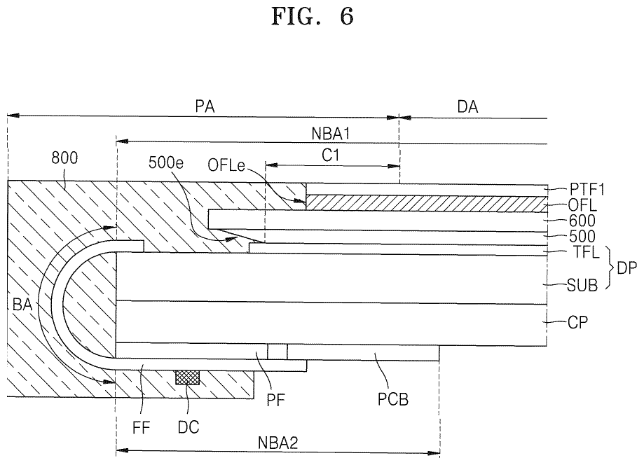

FIGS. 6 to 8 are cross-sectional views of a display device according to embodiments.

Referring to FIG. 6, a cover panel CP may be disposed under the display panel DP. The display panel DP may include a display substrate SUB and the encapsulation layer TFL disposed thereon. For example, the cover panel CP may be disposed under the display substrate SUB of the display panel DP.

A circuit board PCB may be disposed under the cover panel CP. The circuit board PCB may be in contact with one surface of the cover panel CP. An adhesive film PF may be disposed under the cover panel CP. The adhesive film PF may be in contact with one surface of the cover panel CP. The circuit board PCB and the adhesive film PF may be disposed on a bottom surface of the cover panel CP to be adjacent to each other.

A flexible film FF may extend from a front surface of the display substrate SUB. For example, at least a portion of the flexible film FF may be in contact with at least a portion of the front surface of the display substrate SUB. The flexible film FF may include at least a portion of the first non-bending area NBA1, the bending area BA, and at least a portion of the second non-bending area NBA2.

A driving chip DC may be disposed below the cover panel CP while in contact with one surface of the flexible film FF. The driving chip DC may be configured to receive control signals and power voltages and generate and output signals and voltages for driving the display panel DP.

An adhesive layer 500 may be disposed on the display panel DP, and a glass window 600 may be disposed on the adhesive layer 500. An optical functional layer OFL may be disposed on the glass window 600, and a first protection film PTF1 may be disposed on the optical functional layer OFL.

A filler 800 may be disposed in the peripheral area PA, covering top, bottom, and side surfaces of the glass window 600 and a side surface of the adhesive layer 500. The filler 800 may cover a side surface of the display panel DP. In addition, the filler 800 may fill an inner space and an outer space of the bending area BA.

In an embodiment, an end OFLe of the optical functional layer OFL may be disposed in a space C1 between a boundary where the adhesive layer 500 and the display panel DP meet and a boundary between the display area DA and the peripheral area PA. Because the filler 800 covers the end OFLe of the optical functional layer OFL, an end of the filler 800 may also be disposed between the boundary where the adhesive layer 500 and the display panel DP meet and the boundary between the display area DA and the peripheral area PA. For example, the filler 800 may be disposed over an entire side surface 500e of the adhesive layer 500, covering the top of the side surface 500e of the adhesive layer 500.

As light emitted from the display area DA is reflected from inner top and bottom surfaces of the adhesive layer 500, the light may go out toward the peripheral area PA. Thus, light emitted from the display area DA may be emitted through the side surface 500e of the adhesive layer 500. When the end OFLe of the optical functional layer OFL and the end of the filler 800 are disposed in the space C1 between the boundary where the adhesive layer 500 and the display panel DP meet and the boundary between the display area DA and the peripheral area PA, and thus, the filler 800 is disposed over the entire side surface 500e of the adhesive layer 500, covering the top of the side surface 500e of the adhesive layer 500, light emitted upward through the side surface 500e of the adhesive layer 500 may be absorbed by the filler 800 to prevent light leakage of the display device, thereby improving reliability and quality of the display device.

In addition, as light emitted from the display area DA is reflected from inner top and bottom surfaces of the glass window 600, the light may go out toward the peripheral area PA. Thus, light emitted from the display area DA may be emitted through the top, bottom, and side surfaces of the glass window 600. When the filler 800 covers the top, bottom, and side surfaces of the glass window 600, light emitted through the top, bottom, and side surfaces of the glass window 600 may be absorbed by the filler 800 to prevent light from leaking from the peripheral area PA of the display device, thereby improving reliability and quality of the display device.

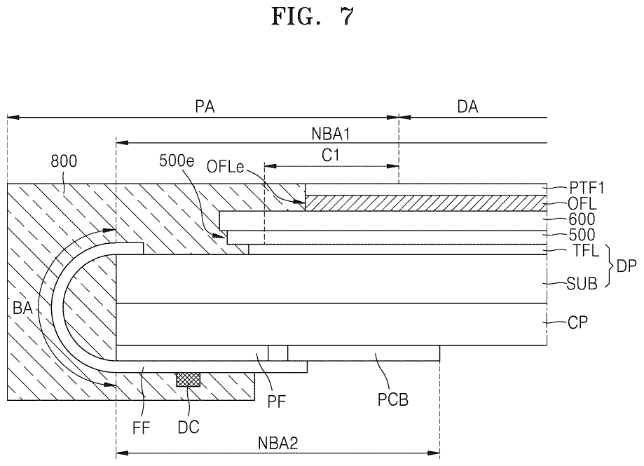

Referring to FIG. 7, in an embodiment, the side surface 500e of the adhesive layer 500 may be straight. Elements except the side surface 500e of the adhesive layer 500 may be the same as those in the embodiment shown in FIG. 6.

In the embodiment in which the side surface 500e of the adhesive layer 500 is straight, the end OFLe of the optical functional layer OFL may be disposed in the space C1 between the side surface 500e of the adhesive layer 500 and a boundary between the display area DA and the peripheral area PA. The filler 800 may cover the end OFLe of the optical functional layer OFL.

When the end OFLe of the optical functional layer OFL and the end of the filler 800 are disposed in the space C1 between the side surface 500e of the adhesive layer 500 and the boundary between the display area DA and the peripheral area PA, and thus, the filler 800 covers the top of the side surface 500e of the adhesive layer 500, light emitted through the side surface 500e of the adhesive layer 500 may be absorbed by the filler 800 to prevent light from leaking from the peripheral area PA of the display device, thereby improving reliability and quality of the display device.

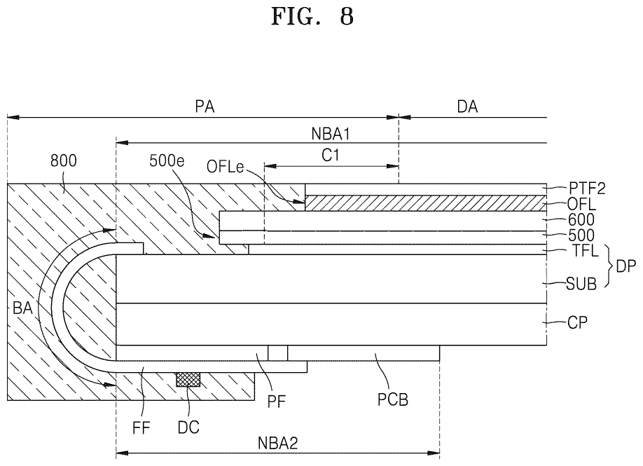

Referring to FIG. 8, the glass window 600 may be disposed on the adhesive layer 500. The glass window 600 may be further disposed between the adhesive layer 500 and the optical functional layer OFL to improve strength of the display device.

When a second protection film PTF2 is disposed on the adhesive layer 500, the second protection film PTF2 and the adhesive layer 500 may be provided as a single body, and a side surface of the second protection film PTF2 and the side surface 500e of the adhesive layer 500 may be in line with one another.

In the embodiment in which the side surface 500e of the adhesive layer 500 and the side surface of the second protection film PTF2 are in line with one another, the end OFLe of the optical functional layer OFL may be disposed in the space C1 between the side surface 500e of the adhesive layer 500 and the boundary between the display area DA and the peripheral area PA. The filler 800 may cover the end OFLe of the optical functional layer OFL.

When the end OFLe of the optical functional layer OFL and the end of the filler 800 are disposed in the space C1 between the side surface 500e of the adhesive layer 500 and the boundary between the display area DA and the peripheral area PA, and thus, the filler 800 covers the top of the side surface 500e of the adhesive layer 500, light emitted through the side surface 500e of the adhesive layer 500 may be absorbed by the filler 800 to prevent light from leaking from the peripheral area PA of the display device, thereby improving reliability and quality of the display device.

According to one or more of the above embodiments, a display device with improved reliability and quality may be implemented. However, one or more embodiments are not necessarily limited by such an effect.

It should be understood that embodiments described herein should be considered in a descriptive sense and not necessarily for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display device, comprising:
a display panel comprising a display area and a peripheral area proximate to the display area, wherein the peripheral area comprises a bending area extending from the display area;
an adhesive layer disposed on the display panel, wherein at least a portion of a side surface of the adhesive layer is inclined;
a glass window disposed on the adhesive layer and protruding toward the peripheral area to a greater extent than the adhesive layer;
an optical functional layer disposed on the glass window, wherein an end of the optical functional layer is between a boundary where the adhesive layer and the display panel meet and a boundary between the display area and the peripheral area; and
a filler disposed in the peripheral area, covering top, bottom, and side surfaces of the glass window and the side surface of the adhesive layer.

2. The display device of claim 1, wherein the filler is disposed over an entire side surface of the adhesive layer, covering a top of the side surface of the adhesive layer.

3. The display device of claim 1, wherein the display panel is bent in the bending area such that bottom surfaces thereof face each other.

4. The display device of claim 3, wherein the filler covers a top surface of the display panel in the bending area.

5. The display device of claim 3, wherein the filler fills a space between the bottom surfaces of the display panel facing each other in the bending area.

6. The display device of claim 1, wherein the filler covers a side surface of the optical functional layer.

7. The display device of claim 1, wherein the display panel comprises a substrate, a display layer, and an encapsulation layer.

8. The display device of claim 1, further comprising a cover window disposed on the display panel.

9. A display device, comprising:
a display panel comprising a display area and a peripheral area proximate to the display area, wherein the peripheral area comprises a bending area extending from the display area;
an adhesive layer disposed on the display panel, wherein a side surface of the adhesive layer is straight;
a glass window disposed on the adhesive layer and protruding toward the peripheral area to a greater extent than the adhesive layer;
an optical functional layer disposed on the glass window, wherein an end of the optical functional layer is between the side surface of the adhesive layer and a boundary between the display area and the peripheral area; and
a filler disposed in the peripheral area, covering top, bottom, and side surfaces of the glass window and the side surface of the adhesive layer.

10. The display device of claim 9, wherein the filler covers a top of the side surface of the adhesive layer.

11. The display device of claim 9, wherein the display panel is bent in the bending area such that bottom surfaces thereof face each other.

12. The display device of claim 11, wherein the filler covers a top surface of the display panel in the bending area.

13. The display device of claim 11, wherein the filler fills a space between the bottom surfaces of the display panel facing each other.

14. The display device of claim 9, wherein the filler covers a side surface of the optical functional layer.

15. A display device, comprising:
a display panel comprising a display area and a peripheral area proximate to the display area, wherein the peripheral area comprises a bending area extending from the display area;
an adhesive layer disposed on the display panel, wherein a side surface of the adhesive layer is straight;
a protection film disposed on the adhesive layer;
an optical functional layer disposed on a glass window, wherein an end of the optical functional layer is between the side surface of the adhesive layer and a boundary between the display area and the peripheral area; and
a filler disposed in the peripheral area, covering top and side surfaces of the protection film and the side surface of the adhesive layer.

16. The display device of claim 15, wherein the side surface of the protection film and the side surface of the adhesive layer are in line with one another.

17. The display device of claim 15, wherein the filler covers a top of the side surface of the adhesive layer.

18. The display device of claim 15, wherein the display panel is bent in the bending area such that bottom surfaces thereof face each other.

19. The display device of claim 18, wherein the filler covers a top surface of the display panel in the bending area and fills a space between the bottom surfaces of the display panel.

20. The display device of claim 15, wherein the filler covers a side surface of the optical functional layer.

21. An electronic device comprising:
a display panel comprising a display area and a peripheral area proximate to the display area, wherein the peripheral area comprises a bending area extending from the display area;
an adhesive layer disposed on the display panel, wherein at least a portion of a side surface of the adhesive layer is inclined;
a glass window disposed on the adhesive layer and protruding toward the peripheral area to a greater extent than the adhesive layer;
an optical functional layer disposed on the glass window, wherein an end of the optical functional layer is between a boundary where the adhesive layer and the display panel meet and a boundary between the display area and the peripheral area;
a filler disposed in the peripheral area, covering top, bottom, and side surfaces of the glass window and the side surface of the adhesive layer; and
a bottom cover constituting an exterior, wherein a front surface of the bottom cover comprises an opening exposing a portion of the display panel.
